(19) United States
(12) Patent Application Publication
(10) Pub. No.: US 2025/0311449 A1
(43) Pub. Date: Oct. 2, 2025

(54) THERMOPHOTOVOLTAIC SYSTEM

(71) Applicant: THE REGENTS OF THE UNIVERSITY OF COLORADO, A BODY CORPORATE, Denver, CO (US)

(72) Inventors: Longji CUI, Boulder, CO (US); Mohammad HABIBI, Boulder, CO (US)

(21) Appl. No.: 18/863,013

(22) PCT Filed: Apr. 28, 2023
(86) PCT No.: PCT/US2023/020336

§ 371 Date: Nov. 5, 2024

Related U.S. Application Data
(60) Provisional application No. 63/339,340, filed on May 6, 2022.
(60) Provisional application No. 63/440,898, filed on Jan. 24, 2023.

(51) Int. Cl. H10F 10/17; H10F 77/42; H10F 77/70

(52) U.S. Cl. CPC H10F 10/17; H10F 77/484; H10F 77/703

(57) ABSTRACT

A thermophotovoltaic device comprises an emitter for emitting photons towards a receiver. The thermophotovoltaic device also comprises an intermediate layer comprising a thermal insulating material with a low thermal conductivity of at most 1.4 W/m-K. The intermediate layer is positioned between the emitter and the receiver. The receiver comprising a photovoltaic cell configured to convert at least a portion of the photons into electric energy.

### CROSS-REFERENCE TO RELATED APPLICATIONS

This application claims the benefit of and priority to U.S. Provisional Patent Application Ser. No. 63/339,340 filed on May 6, 2022 and entitled “Thermophotovoltaic system without a vacuum or air gap,” and to U.S. Provisional Patent Application Ser. No. 63/440,898 filed on Jan. 24, 2023 and entitled “Thermophotovoltaic system without a vacuum or air gap,” both of which applications are expressly incorporated herein by reference in their entirety.

### BACKGROUND

More than 60% of total world energy consumption every year ends up as waste heat. In the US only, waste heat originating from commercial, residential, and industrial sectors, amounts to 65 Quads, which is about equal to the energy contained in 65 trillion cubic feet of natural gas, 2925 million tons of coal, or 11 trillion barrels of crude oil. Such a vast renewable energy source has been largely untapped due to the lack of effective energy conversion technology that could capture and convert the waste heat into usable electrical energy. Limited technologies existing to harvest waste heat include thermoelectrical generator and thermophotovoltaics. However, there is no wide deployment so far for industrial and domestic applications based on these technologies because of their low energy conversion efficiency, high module cost (not scalable), and less power generation stability.

The subject matter claimed herein is not limited to embodiments that solve any disadvantages or that operate only in environments such as those described above. Rather, this background is only provided to illustrate one exemplary technology area where some embodiments described herein may be practiced.

### BRIEF SUMMARY

Disclosed embodiments include a thermophotovoltaic device comprising an emitter for emitting photons towards a receiver. The thermophotovoltaic device comprises an intermediate layer comprising a thermal insulating material with a low thermal conductivity of at most 1.4 W/m-K. The intermediate layer is positioned between the emitter and the receiver. The receiver comprising a photovoltaic cell configured to convert at least a portion of the photons into electric energy.

Additionally disclosed embodiments include a method for fabricating a thermophotovoltaic device with a zero-gap intermediate layer. The method comprises positioning an emitter for emitting photons towards a receiver. The method also comprises coupling an intermediate layer between the emitter and the receiver. The intermediate layer comprises a thermal insulating material with a thermal conductivity of at most 1.4 W/m-K. Further, the method comprises positioning the receiver comprising a photovoltaic cell configured to convert at least a portion of the photons into electric energy.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Additional features and advantages will be set forth in the description which follows, and in part will be obvious from the description, or may be learned by the practice of the teachings herein. Features and advantages of the invention may be realized and obtained by means of the instruments and combinations particularly pointed out in the appended claims. Features of the present invention will become more fully apparent from the following description and appended claims, or may be learned by the practice of the invention as set forth hereinafter.

### BRIEF DESCRIPTION OF THE DRAWINGS

In order to describe the manner in which the above-recited and other advantages and features can be obtained, a more particular description of the subject matter briefly described above will be rendered by reference to specific embodiments which are illustrated in the appended drawings. Understanding that these drawings depict only typical embodiments and are not therefore to be considered to be limiting in scope, embodiments will be described and explained with additional specificity and detail through the use of the accompanying drawings described below.

FIG. 1 illustrates an embodiment of a zero-gap thermophotovoltaics (zero-gap TPV).

FIG. 2A illustrates a chart describing attributes of a zero-gap TPV.

FIG. 2B illustrates another chart describing attributes of a zero-gap TPV.

FIG. 3 illustrates another embodiment of a zero-gap TPV.

FIG. 4A illustrates a chart describing attributes of a zero-gap TPV.

FIG. 4B illustrates another chart describing attributes of a zero-gap TPV.

FIG. 4C illustrates another chart describing attributes of a zero-gap TPV.

FIG. 5 illustrates a flowchart of a method for fabricating a thermophotovoltaic device with a zero-gap intermediate layer.

### DETAILED DESCRIPTION

“Zero-gap Thermophotovoltaics (zero-gap TPV),” can address the long-standing challenges in waste heat harvesting by employing a fundamentally different physical principle from the existing technologies. Using zero-gap TPV disclosed embodiments eliminate the need of a vacuum or air gap in traditional gap-based TPVs, which is an obstacle that impedes the proliferation of TPVs and limited the large-scale cost-effective manufacturing. In at least one embodiment, an infrared-transparent intermediate layer is inserted between the thermal emitter and PV receiver as a functional component in the zero-gap TPVs.

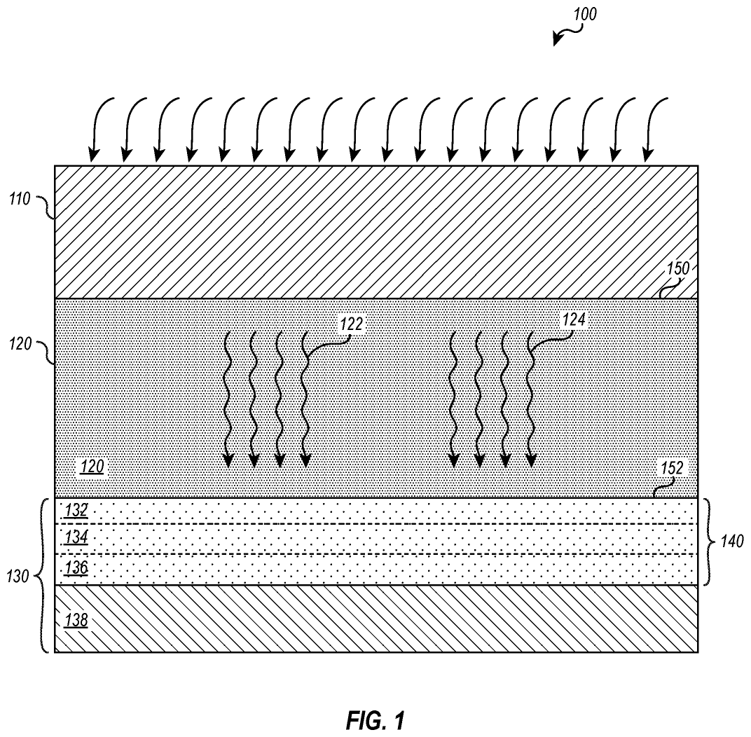

FIG. 1 illustrates an embodiment of a zero-gap TPV module 100. The depicted zero-gap TPV module 100 comprise an emitter 110 for emitting photons towards a receiver 130. An intermediate layer 120 is positioned between the emitter 110 and the receiver 130. The receiver 130 comprises a photovoltaic cell configured to convert at least a portion of the photons into electric energy. The depicted photovoltaic cell 140 comprises a P region 132, a Depletion region 134, and a N region 136. The receiver 130 may also comprise gold reflector layer 138.

In at least one embodiment, the intermediate layer 120 may comprise a thermal insulating material with a low thermal conductivity of at most 1.4 W/m-K, the intermediate layer 120 positioned between the emitter and the receiver. Additionally or alternatively, the intermediate layer 120 further comprises a reflective index of at least 1.4. The intermediate layer 120 may comprise a substantially infrared and visible spectrum-transparent material. For example, the intermediate layer 120 comprises glass.

In at least one embodiment, the intermediate layer 120 comprises a transparency to the wavelength range of 0.5-2.5 μm. Additionally or alternatively, the intermediate layer 120 comprises ability to withstand high temperatures (>1000 degree Celsius). Further, the intermediate layer 120 may comprise a low thermal conductivity (as low as possible, for example glass has 1.4 W/m·K of thermal conductivity). The intermediate layer 120 may also comprise a high refractive index (as high as possible, glass is ˜1.5, GaAs is ˜3.3). Example materials for the intermediate layer 120 may comprise glass, GaAS, Si, InP, CdTe, CdS, or some other similar material. High-K propagating waves 122 and low-K propagating waves 124 may travel through the intermediate layer 120.

This new multilayer structure, serving as an effective IR waveguide, supports a much higher energy conversion efficiency and stable high-power generation. By replacing the vacuum or air gap with a solid-state layer, zero-gap TPV module 100 can be fabricated as a whole and easily scaled up without the difficulties of costly hermetic seal and packaging. This can bring down the single module cost significantly, as well as enable large system level installation and integration.

The intermediate layer 120 inserted between the thermal emitter 110 and PV receiver 130, replacing the vacuum or air gap, serves as a lossless waveguide for frustrated infrared photons. The loss effects, potentially from the material type, geometry, and optical transmission, could significantly affect the energy conversion performance. A zero-gap TPV module 100 is inherently a multi-layer optical structure that functions as a power generator. Interfaces between the layers within the zero-gap TPV determine at least some of the optical properties, and thus the energy conversion efficiency.

In order to calculate the power generation in a zero-gap TPV module 100, the first step is calculating the thermal radiation that reaches to the receiver 130 from emitter 110. Net radiation between emitter 110 and receiver 130 is obtained by solving Maxwell's equations, and then applying fluctuation-dissipation theorem to them. One of the methods that is useful for solving Maxwell's equations is using dyadic Green's functions. In this regard, because of the existence of several layers, the thermal radiation can be obtained by solving dyadic Green's functions in a multilayered structure by using scattering matrix method. Thus, based on this method, the radiation heat flux between emitter layer, with a temperature of Tₑ and a thickness of Zₛ₊₁-Zₛ, and receiver layer with a temperature of Tᵣ at a location of Z_{c} in a multilayered structure can be obtained by the following equation:

$${q}_{ω , s l} ( {z}_{c} ) = \frac{{k}_{v}^{2} θ ( ω , {T}_{s} )}{{π}^{2}} Re \{ i {ε}_{rs}^{″} ( ω ) {\int }_{0}^{∞} {k}_{ρ} {dk}_{ρ} {\int }_{{z}_{s}}^{{z}_{s + 1}} {dz}^{′} [ \begin{matrix}{g}_{s l ρ ρ}^{E} ( {k}_{ρ} , {z}_{c} , {z}^{′} , ω ) {g}_{s l θ ρ}^{H *} ( {k}_{ρ} , {z}_{c} , {z}^{′} , ω ) + \\ {g}_{s l ρ z}^{E} ( {k}_{ρ} , {z}_{c} , {z}^{′} , ω ) {g}_{s l θ z}^{H *} ( {k}_{ρ} , {z}_{c} , {z}^{′} , ω ) - \\ {g}_{s l θ θ}^{E} ( {k}_{ρ} , {z}_{c} , {z}^{′} , ω ) {g}_{s l ρ θ}^{H *} ( {k}_{ρ} , {z}_{c} , {z}^{′} , ω )\end{matrix} ] \} \qquad ( 1 )$$

where, k is a parallel component of wave vector, g^{E} and g^{H} are Weyl components of the electric and magnetic dyadic Green's functions, θ(ω,T) represents the mean energy of Planck oscillator at temperature of T and frequency of ω. The detail of Weyl components of the electric and magnetic dyadic Green's functions and also the computational algorithm that is applied to solve the equation are known to one having skill in the art.

In order to predict the power generation in the PV cell, the carrier transport in a P-N junction 132 is modeled by solving the steady-state continuity equation numerically with finite difference method as follows:

$${D}_{( e , h )} \frac{{d}^{2} Δ {n}_{( e , h ) , ω} ( z )}{d {z}^{2}} - \frac{Δ {n}_{( e , h ) , ω} ( z )}{{τ}_{( e , h )}} + {g}_{ω} ( z ) = 0 \qquad ( 2 )$$

where D_{(e,h)} is a diffusion coefficient of electrons and holes, n_{(e,h)} is electron and hole concentration, g_{ω} is electron-hole pairs generation rate, and T_{(e,h)} is lifetime of electron/hole. An is the difference between local carrier concentration (n_{(e,h)}) and equilibrium carrier concentration (n_{(e,h)0}). The equilibrium carrier concentration (n_{(e,h)0}) depends on the intrinsic carrier concentration (nᵢ) and can be calculated by n_{(e,h)0}=nᵢ²/N_{(a,d)}. The lifetime of electron/hole can be obtained by taking into account the photon recycling of radiative recombination lifetime φ_{PR}τ_{RR}, non-radiative Auger recombination lifetime τ_{Auger}, and non-radiative Shockley-Read-Hall (SRH) recombination lifetime τ_{SRH} as follows:

$${τ}_{( e , h )} = {( \frac{1}{{φ}_{PR} {τ}_{R R}} + \frac{1}{{τ}_{Auger}} + \frac{1}{{τ}_{SRH}} )}^{- 1} \qquad ( 3 )$$

The electron-hole pairs generation rate (go) can be calculated by using the thermal radiation model as follows:

$${g}_{j , ω} = \frac{1}{\overline{h} ω} \frac{{q}_{w , {Δz}_{j}^{( p , n )}}^{a b s}}{Δ {z}_{j}^{( p , n )}} \qquad ( 4 )$$

where, q is the net radiation heat transfer between emitter and the considered layer in the PV cell with thickness of ΔZⱼ.

In order to solve the equation (2), four boundary conditions are needed. At the top and bottom sides of the PV cell, recombination of electron-hole pairs is happened. Therefore, by considering a recombination velocity in these surfaces, the following equation can be applied for the boundary conditions:

$${D}_{( e , h )} \frac{d Δ {n}_{( e , h ) , ω} ( {z}_{( top , bottom )} )}{d z} = {S}_{( e , h )} Δ {n}_{( e , h ) , ω} ( {z}_{( top , bottom )} ) \qquad ( 5 )$$

Moreover, at the top and bottom sides of the depletion region, it is assumed that all the generated electron-hole pairs are swept, so recombination does not happen at these two boundaries. The thickness of depletion region can be obtained by the following equation:

$${L}_{dp} = {[ \frac{2 {ε}_{s}}{e} {V}_{0} ( \frac{1}{{N}_{a}} + \frac{1}{{N}_{d}} ) ]}^{1 / 2} \qquad ( 6 )$$

where, εₛ represents the static relative permittivity, V₀ represents the equilibrium voltage of the p-n junction that can be calculated by V₀=(k_{b}T/e)ln(NₐN_{d}/nᵢ²).

After solving the equation (2) and obtaining the carrier distribution in the PV cell, in order to predict the power generation in the PV cell, first the generated current should be obtained. The generated current generation is a summation of generated currents in the depletion, P and N regions. It is assumed that all the generated electron-hole pairs in the depletion region generate current, so the generated current in the depletion region can be calculated as follows:

$${J}_{do , ω} = e {\int }_{{z}_{dp}^{p}}^{{z}_{dp}^{n}} {g}_{j , ω} d z \qquad ( 7 )$$

A lot of electron-hole pairs are generated in the P and N regions. However, because of the recombination in these regions, these generated electron-hole pairs can generate current only if they reach to the edges of depletion region. In this regard, the generated currents in P and N region depend on gradient of carrier concentration in the edges of depletion region and can be calculated as follows:

$${J}_{e , ω} = {eD}_{e} \frac{d Δ {n}_{e , ω} ( {z}_{d p}^{p} )}{d z} \qquad ( 8 )$$

$${J}_{h , ω} = - {eD}_{h} \frac{d Δ {n}_{h , ω} ( {z}_{d p}^{n} )}{d z} \qquad ( 9 )$$

Thus, the total generated photocurrent is obtained as follows:

$${J}_{ph , ω} = {J}_{e , ω} + {J}_{h , ω} + {J}_{dp , ω} \qquad ( 10 )$$

When there is no radiation on the PV cell, there is a current in the P-N junction that is called dark current (J₀) because of applied voltage on the cell. When the photocurrent is generated in the PV cell due to the radiation, the generated photocurrent opposes the dark current. The dark current can be calculated by solving the equation (2) while the source term is zero (g=0). After obtaining the dark current, I-V curve of PV cell is obtained by using J(V_{f})=Jₚₕ−J₀(V_{f}) and then the power generation can be calculated.

The power conversion efficiency of PV cell is defined as the ratio of power generation to the net radiation heat transfer form emitter to PV cell. However, the power conversion efficiency of the TPV system is defined as the ratio of power generation to the total heat transfer form emitter to PV cell which consists of radiation and conduction.

The optical properties of In_{0.18}Ga_{0.82}Sb, GaAs, ZrN, and Au is known to those having skill in the art. The Intrinsic Carrier Concentration of In_{0.18}Ga_{0.82}Sb is assumed to be 2.22×10¹³ cm⁻³. The electron and hole diffusion coefficients are assumed to be 35.2 cm²s⁻¹ and 18.3 cm²s⁻¹ respectively. The surface recombination velocity at the top and bottom of the PV cell is 2×10⁴ and 0 m·s⁻¹. The non-radiative recombination lifetime of electron and hole of In_{0.18}Ga_{0.82}Sb are 9.8 ns and 31.1 ns respectively. Moreover, the radiative recombination lifetime of electron and hole of In_{0.18}Ga_{0.82}Sb are 13 ns and 1.27 μs respectively.

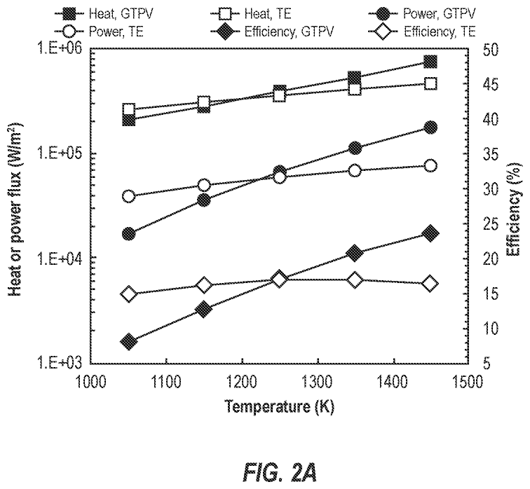

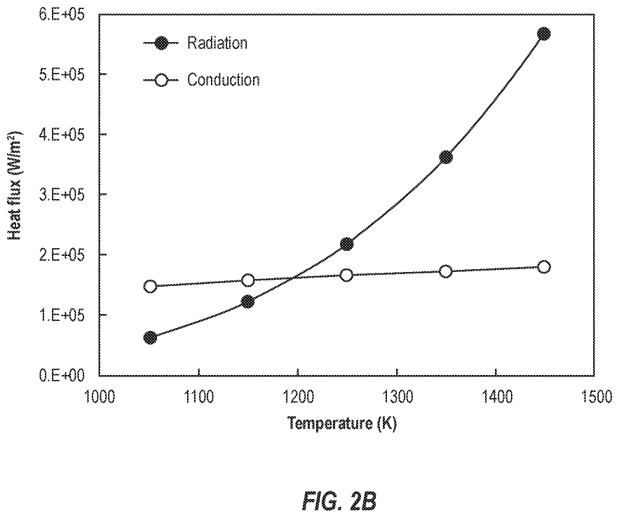

FIG. 2A draws a comparison between the performance of zero-gap TPV module 100 and thermoelectric (TE) system. According to this figure, the heat transfer between high and low temperature sources is higher for the zero-gap TPV module 100 when the emitter temperature is higher than 1250 K. To identify the reason for this issue, FIG. 2B shows the contribution of radiation and conduction in the heat transfer between hot and cold sides of the zero-gap TPV system. According to this figure, the radiation heat transfer becomes higher than conduction when the emitter temperature is higher than 1200 K. Thus, because of the higher radiation contribution in heat transfer, the heat transfer of Zero-gap TPV module 100 is higher than TE systems in high temperature. Therefore, this issue is a good potential for higher power generation in zero-gap TPV. Moreover, beside the higher heat transfer in zero-gap TPV module 100, the power conversion efficiency of zero-gap TPV is significantly higher than TE module in high temperature. According to FIG. 2A, the efficiency of zero-gap TPV and TE module show completely different trend by increasing the emitter temperature. For a zero-gap TPV module 100, the efficiency is enhanced noticeably by increasing the temperature. This can be attributed to the two different facts. First, due to the band gap of 0.56 eV, by increasing the emitter temperature, the emission spectrum has higher energy flux in frequencies of higher than bandgap, so the efficiency is increased by increasing the emitter temperature. Second, the conduction part of heat transfer between emitter and PV cell 140 does not generate power in zero-gap TPV module 100. According to FIG. 2B, by increasing the emitter temperature, the ratio between radiation and conduction increases significantly, so it causes the system efficiency to be improved.

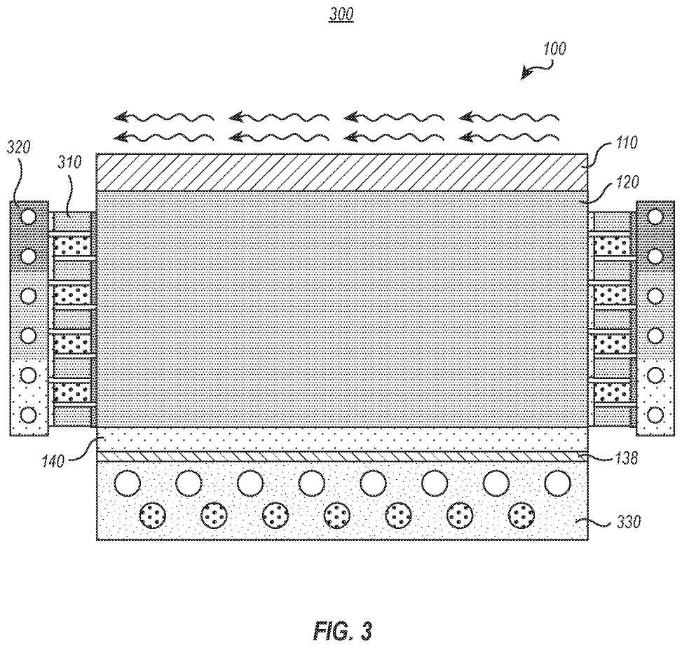

FIG. 3 shows the heat conduction and radiation in the proposed combined heat and power generation system 300. According to this figure, using a TE module 310 and side heat collector 320 increases the heat conduction in the system significantly. When the length of TE module 310 and side heat collector 320 is 7.5 cm, the radiation is higher than conduction for emitter temperature of 1300 K, while the conduction is always higher than radiation when the length of TE module 310 is 9.5 cm. On the other hand, the radiation is the same for all the cases.

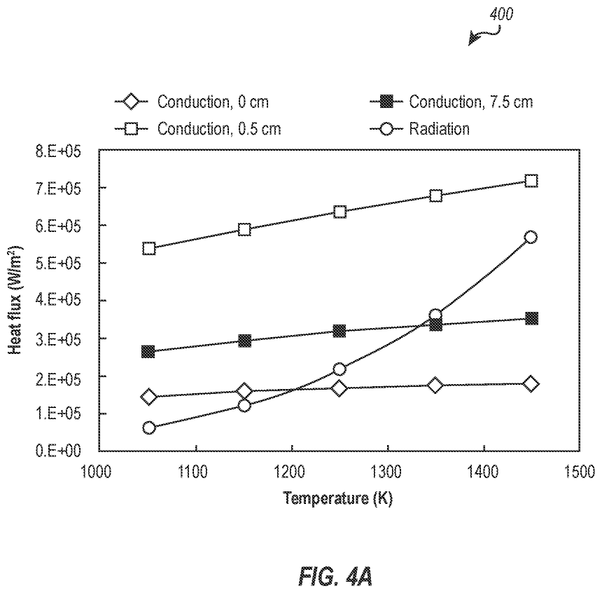

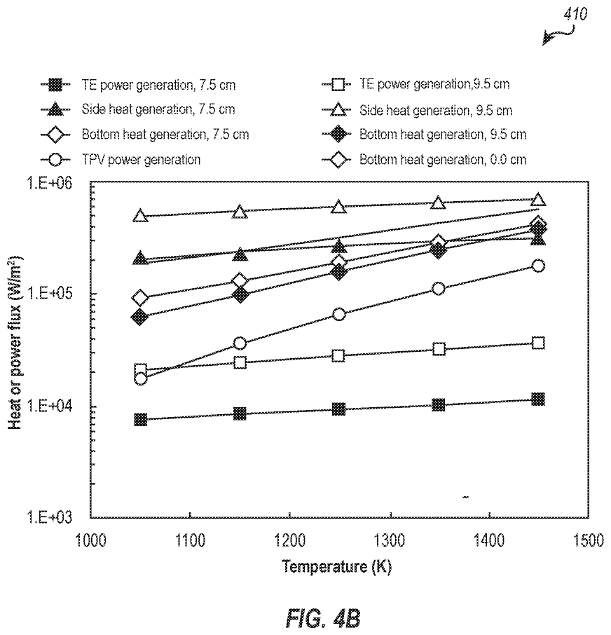

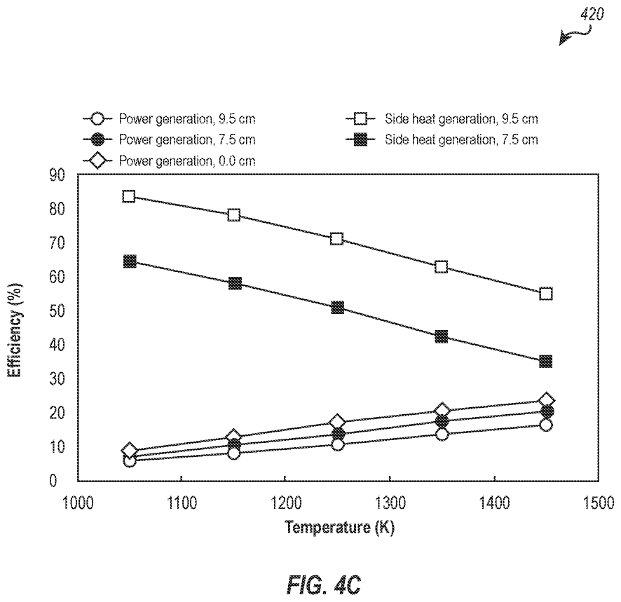

FIG. 4A shows a chart 400 of the power generation in the TE and the TPV and also the heat generation inside and on the bottom heat collector for three different lengths of TE module 310. According to this figure, the power generation with the TPV module 100 is higher than TE module 310 for approximately all the emitter temperatures and TE lengths. When the emitter 110 temperature is lower than 1100 and the length of the TE module 310 is 9.5 cm, the TE module 310 generates more power than TPV module 100. There are two reasons for generating more power by the TPV module 100 in comparison to the TE modules 310. First, the temperature difference between both sides of TE modules 310 is significantly lower than that of the TPV module 100, so it has a lower potential for power generation. Second, the power conversion efficiency of TPV module 100 is higher than that of the TE module 310, so the TPV module 100 has the more ability to generate power.

Moreover, according to FIG. 4A, the side heat generation is always higher than bottom heat generation because there is a higher heat conductance between the hot surface and the side heat collector, so the heat is absorbed more by the side heat collector. According to this figure, by increasing the length of TE module, the side heat generation is increased while the bottom heat generation is decreased. This can be attributed to the fact that by increasing the length of TE module and side heat collector, the intermediate slab becomes cooler and cooler, so the lower heat conduction is absorbed by the bottom heat collector. So, the length of TE module 310 and side heat collector 320 are good design parameters for adjusting the heat generation in the bottom heat collector 330 and side collectors 320. The difference between the side and the bottom heat generation is the side heat collector 320 generates a higher potential heat because the outlet water temperature of side heat collector 320 is 90° C. while the outlet water temperature of bottom heat collector 330 is a few degrees of Celsius higher than ambient temperature, so the side heat generation is higher potential heat source.

Furthermore, according to the FIG. 4A, by increasing the emitter temperature, the difference between the bottom heat generation when the length of TE module 310 is 7.5 cm and 9.5 cm becomes smaller and smaller. Moreover, the slope of increment of bottom heat generation is higher than that of the side heat generation. This can be attributed to the fact that by increasing the emitter 110 temperature, the radiation that is absorbed by the PV cell 140 is increased significantly. Thus, a major part of the heat that is absorbed by the bottom heat collector 330 comes from radiation. In this regard, because the radiation is the same for different lengths of the TE module 310 and side heat collector 320, the amount of bottom heat generation tends to go to the same value by increasing the emitter temperature. Moreover, because of the aforementioned reason, the bottom heat generation follows the trend of radiation heat flux by increasing the emitter temperature. Therefore, because the radiation, in comparison to the conduction, is increased more and more by increasing the emitter temperature, the bottom heat generation, in comparison to the side one, shows a rapid increment with increasing the temperature.

FIG. 4B shows the efficiency of power generation and side heat generation for different lengths of the TE modules 310 and the side heat collectors 320. According to this figure, by increasing the length of the TE module 310 and the side heat collector 320 from 0 to 9.5 cm, the power conversion efficiency is reduced. This can be attributed to the fact by increasing the length of the TE module 310, the TE power generation is increased, so the contribution of TE power generation is increased. Because the power conversion efficiency of the TE module 310 is smaller than TPV module 100, it reduces the total power conversion efficiency of the system.

Furthermore, by increasing the emitter temperature, the difference between power conversion efficiency of system with different TE module lengths is increased. This can be attributed to the fact that by increasing the emitter temperature, the efficiency of the TPV module 100 is increased significantly, so the gap between efficiency of TPV and TE is increased. Therefore, increasing the length of the TE modules 310 in higher emitter temperature, reduces the power conversion efficiency of the system more and more. Moreover, according to this figure, the power conversion efficiency is increased by increasing the emitter temperature. This can be attributed to the fact that by increasing the emitter temperature, the TPV power conversion efficiency is increased, so it causes the system to have higher efficiency. However, by increasing the emitter temperature, the contribution of side heat generation is decreased. This can be attributed to the fact that by increasing the emitter temperature, the radiation part of the incoming heat is increased. Because the radiation is absorbed by the PV cell, most of the radiation heat flux is absorbed by bottom heat collector 330. Thus, it causes the side heat collector 320 to absorb less part of incoming heat flux from the emitter when the emitter temperature is increased.

In at least one embodiment, the TPV module 100 comprises several different interfaces between the different layers. For example, an emitter interface 150 (shown in FIG. 1) is located between the intermediate layer 120 and the emitter 110. Additionally, a receiver interface 152 is located between the intermediate layer 120 and the receiver 130. In at least one embodiment, the receiver interface 152 between the intermediate layer 120 and the receiver 130 comprises an optical epoxy. For example, when constructing the TPV module 100 the manufacturer may bond the intermediate layer 120 with the receiver 130 within an optical epoxy. The optical epoxy may appear substantially transparent to radiation travelling through the intermediate layer 120.

Additionally or alternatively, in at least one embodiment, the emitter interface 150 between the intermediate layer 120 and the emitter 110 comprises a surface with nanometer-scale roughness. The emitter 110 and the intermediate layer 120 may then be bonded through a pressure connection where the two components are pressed together along the nanometer-scale roughness surfaces. In at least one embodiment, a pressure of 20 to 60 psi is sufficient for bonding the emitter 110 and the intermediate layer 120.

Additionally or alternatively, in at least one embodiment the emitter 110 comprises a film that is directly applied to the intermediate layer 120. For example, the film may have adhered to the intermediate layer 120 such that no additional pressure or action is needed to form the desired bond.

Additionally, in at least one embodiment, the receiver interface 152 between the intermediate layer 120 and the receiver 130 comprises a first nano-pattern fabricated on a surface of the receiver 130 and a second interconnecting nano-pattern on a surface of the intermediate layer 120. The second interconnecting non-pattern may comprise parallel lines that are configured to interconnect with parallel lines in the first nano-pattern. Various other patterns that provide some lateral friction may be utilized.

The following discussion now refers to a number of methods and method acts that may be performed. Although the method acts may be discussed in a certain order or illustrated in a flow chart as occurring in a particular order, no particular ordering is required unless specifically stated, or required because an act is dependent on another act being completed prior to the act being performed.

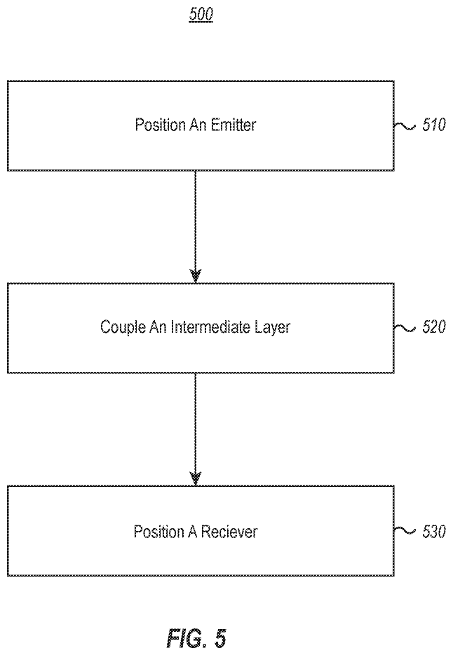

FIG. 5 shows a flowchart in a method 500 for fabricating a thermophotovoltaic device with a zero-gap intermediate layer. Method 500 includes an act 510 of positioning an emitter 110. Act 510 comprises positioning an emitter 110 for emitting photons towards a receiver 130. For example, during manufacture of the TPV module 100, the emitter 110 is positioned on one side of an intermediate layer 120 and the receiver 130 is positioned on the other side.

Method 500 additionally includes an act 520 of coupling an intermediate layer. Act 510 comprises coupling an intermediate layer 120 between the emitter 110 and the receiver 130. The intermediate layer 120 comprises a thermal insulating material with a thermal conductivity of at most 1.4 W/m-K. For example, the emitter 110 may be coupled to the intermediate layer 120 through nano-scale course surfaces that are pressed together. Further, the intermediate layer 120 may be coupled to the receiver 130 through an optical epoxy.

Method 500 also includes an act 530 of positioning the receiver 130. Act 530 comprises positioning the receiver 130. The receiver 130 comprises a photovoltaic cell 140 configured to convert at least a portion of the photons into electric energy.

The present invention may be embodied in other specific forms without departing from its spirit or characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

1. A thermophotovoltaic device comprising:
an emitter for emitting photons towards a receiver;
an intermediate layer comprising a thermal insulating material with a low thermal conductivity of at most 1.4 W/m-K, the intermediate layer positioned between the emitter and the receiver; and
the receiver comprising a photovoltaic cell configured to convert at least a portion of the photons into electric energy.

2. The thermophotovoltaic device of claim 1, wherein the intermediate layer further comprises a reflective index of at least 1.4.

3. The thermophotovoltaic device of claim 2, wherein the intermediate layer comprises a substantially infrared and visible spectrum-transparent material.

4. The thermophotovoltaic device of claim 3, wherein the intermediate layer comprises glass.

5. The thermophotovoltaic device of claim 1, wherein a receiver interface between the intermediate layer and the receiver comprises optical epoxy.

6. The thermophotovoltaic device of claim 1, wherein a receiver interface between the intermediate layer and the receiver comprises a first nano-pattern fabricated on a surface of the receiver and a second interconnecting nano-pattern on a surface of the intermediate layer.

7. The thermophotovoltaic device of claim 1, wherein an emitter interface between the intermediate layer and the emitter comprises a surface with a nanometer-scale roughness.

8. A method for fabricating a thermophotovoltaic device with a zero-gap intermediate layer comprising:
positioning an emitter for emitting photons towards a receiver;
coupling an intermediate layer between the emitter and the receiver, the intermediate layer comprising a thermal insulating material with a thermal conductivity of at most 1.4 W/m-K; and
positioning the receiver comprising a photovoltaic cell configured to convert at least a portion of the photons into electric energy.

9. The method of claim 8, wherein the intermediate layer further comprises a reflective index of at least 1.4.

10. The method of claim 9, wherein the intermediate layer comprises a substantially infrared and visible spectrum-transparent material.

11. The method of claim 10, wherein the intermediate layer comprises glass.

12. The method of claim 8, wherein coupling the intermediate layer between the emitter and the receiver comprises applying an optical epoxy to an interface between the intermediate layer and the receiver.

13. The method of claim 8, wherein coupling the intermediate layer between the emitter and the receiver comprises:
fabricating a first nano-pattern on a surface of the receiver, and
fabricating a second interconnecting nano-pattern on a surface of the intermediate layer.

14. The method of claim 8, wherein an emitter interface between the intermediate layer and the emitter comprises a surface with a nanometer-scale roughness.

15. The method of claim 14, further comprising applying a pressure between the intermediate layer and the surface of the emitter.
